(19) United States
(12) Patent Application Publication
(10) Pub. No.: US 2026/0114015 A1
(43) Pub. Date: Apr. 23, 2026

(54) GATE COUPLING STRUCTURE

(71) Applicant: QUALCOMM Incorporated, San Diego, CA (US)

(72) Inventors: John Jianhong ZHU, San Diego, CA (US); Junjing BAO, San Diego, CA (US); Abhishek JAIN, San Diego, CA (US); Giridhar NALLAPATI, San Diego, CA (US)

(21) Appl. No.: 18/924,806

(22) Filed: Oct. 23, 2024

(51) Int. Cl. H01L 29/417; H01L 23/522; H01L 23/528; H01L 29/423; H01L 29/775

(52) U.S. Cl. CPC H10D 64/258; H10D 30/43; H10D 30/6219; H10D 30/6729; H10D 30/6735; H10W 20/42; H10W 20/427

(57) ABSTRACT

A chip includes a first source/drain, a second source/drain, and a gate between the first source/drain and the second source/drain, wherein the gate includes a ledge extending from a first side of the gate. The chip also includes one or more channels coupled between the first source/drain and the second source/drain, wherein the one or more channels pass through the gate. The chip further comprises a gate coupling structure disposed on the gate.

### BACKGROUND

### Field

Aspects of the present disclosure relate generally to semiconductors, and more particularly, to gate coupling structures.

### Background

A chip includes many active devices for performing various functions on the chip. The transistors may be implemented using gate-all-around field effect transistors (GAAFETs), fin field effect transistors (FinFETs), and/or other types of transistors. The chip may also include backside metal layers under the transistors. The backside metal layers may be patterned, for example, to provide a backside power distribution network (BSPDN) for delivering power to the transistors.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first source/drain, a second source/drain, and a gate between the first source/drain and the second source/drain, wherein the gate includes a ledge extending from a first side of the gate. The chip also includes one or more channels coupled between the first source/drain and the second source/drain, wherein the one or more channels pass through the gate. The chip further comprises a gate coupling structure disposed on the gate.

A second aspect relates to a chip. The chip includes a first source/drain, a second source/drain, a gate between the first source/drain and the second source/drain, and one or more channels coupled between the first source/drain and the second source/drain, wherein the one or more channels pass through the gate. The chip also includes a gate coupling structure contacting a top surface of the gate and a first side of the gate.

A second aspect relates to a chip. The chip includes a first source/drain, a second source/drain, a gate between the first source/drain and the second source/drain, and one or more channels coupled between the first source/drain and the second source/drain, wherein the one or more channels pass through the gate. The chip also includes a gate coupling structure disposed on the gate, wherein a portion of the gate coupling structure extends over a portion of the first source/drain. The chip also includes an insulating layer between the portion of the gate coupling structure and the portion of the first source/drain.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a FinFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary structure including diffusion regions, gates, and frontside contacts according to certain aspects of the present disclosure.

FIG. 3A shows a top view of an exemplary structure including diffusion regions, gates, a frontside contact, and backside contacts according to certain aspects of the present disclosure.

FIG. 3B shows an example of a first cross-sectional view of the structure of FIG. 3A according to certain aspects of the present disclosure.

FIG. 3C shows an example of a second cross-sectional view of the structure of FIG. 3A according to certain aspects of the present disclosure.

FIG. 3D shows a top view of the structure of FIG. 3A further including signal routing according to certain aspects of the present disclosure.

FIG. 4 shows a cross-sectional view of an example of a gate coupling structure contacting a top surface and a side surface of a gate according to certain aspects of the present disclosure.

FIG. 5A shows an example of a structure including epitaxial (epi) layers, spacers, and sacrificial layers according to certain aspects of the present disclosure.

FIG. 5B shows an example in which insulating material is deposited on the structure of FIG. 5A according to certain aspects of the present disclosure.

FIG. 5C shows an example in which the sacrificial layers are released and replaced with gate metal to form a gate according to certain aspects of the present disclosure.

FIG. 5D shows an example in which a frontside contact is formed next to the gate according to certain aspects of the present disclosure.

FIG. 5E shows an example in which additional insulating material is deposited on the structure of FIG. 5D according to certain aspects of the present disclosure.

FIG. 5F shows an example in which a portion of the insulating material and a portion of one of the spacers are etched away to form a hole exposing a top surface and a side surface of the gate according to certain aspects of the present disclosure.

FIG. 5G shows an example in which conductive material is deposited in the hole to form a gate coupling structure according to certain aspects of the present disclosure.

FIG. 6 shows a cross-sectional view of a gate coupling structure and an etch stop layer according to certain aspects of the present disclosure.

FIG. 7A shows another example of a structure including epi layers, spacers, and sacrificial layers according to certain aspects of the present disclosure.

FIG. 7B shows an example in which insulating material is deposited on the structure of FIG. 7A according to certain aspects of the present disclosure.

FIG. 7C shows an example of an etch stop layer formed on the insulating material according to certain aspects of the present disclosure.

FIG. 7D shows an example in which the sacrificial layers are released and replaced with gate metal to form a gate according to certain aspects of the present disclosure.

FIG. 7E shows an example in which a frontside contact is formed next to the gate according to certain aspects of the present disclosure.

FIG. 7F shows an example in which a portion of the insulating material is etched away to form a hole exposing a top surface of the gate according to certain aspects of the present disclosure.

FIG. 7G shows an example in which a sidewall of the etch stop layer is removed according to certain aspects of the present disclosure.

FIG. 7H shows an example in which additional insulating material is etched away according to certain aspects of the present disclosure.

FIG. 7I shows an example in which a portion of one of the spacers is etched away to expose a side surface of the gate according to certain aspects of the present disclosure.

FIG. 7J shows an example in which conductive material is deposited in the hole of FIG. 7I to form a gate coupling structure according to certain aspects of the present disclosure.

FIG. 8A shows a top view of a gate coupling structure and a gate including a ledge according to certain aspects of the present disclosure.

FIG. 8B shows a cross-sectional view of the gate coupling structure and the ledge according to certain aspects of the present disclosure.

FIG. 9 shows an example in which the ledge is extended in a y direction according to certain aspects of the present disclosure.

FIG. 10A shows an example of a structure including epi layers, spacers, insulating material, and sacrificial layers according to certain aspects of the present disclosure.

FIG. 10B shows an example in which a portion of the insulating material and a portion of one of the spacers are etched away to form a hole according to certain aspects of the present disclosure.

FIG. 10C shows an example in which the sacrificial layers are released and replaced with gate metal to form a gate including a ledge according to certain aspects of the present disclosure.

FIG. 10D shows an example in which a frontside contact is formed next to the gate according to certain aspects of the present disclosure.

FIG. 10E shows an example in which additional insulating material is deposited on the structure of FIG. 10D according to certain aspects of the present disclosure.

FIG. 10F shows an example which a gate coupling structure is formed on the gate including the ledge according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

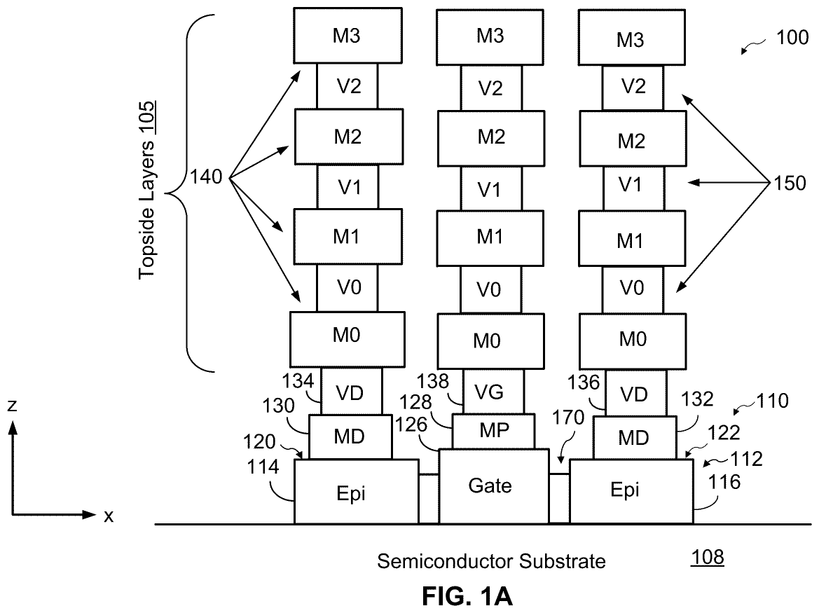

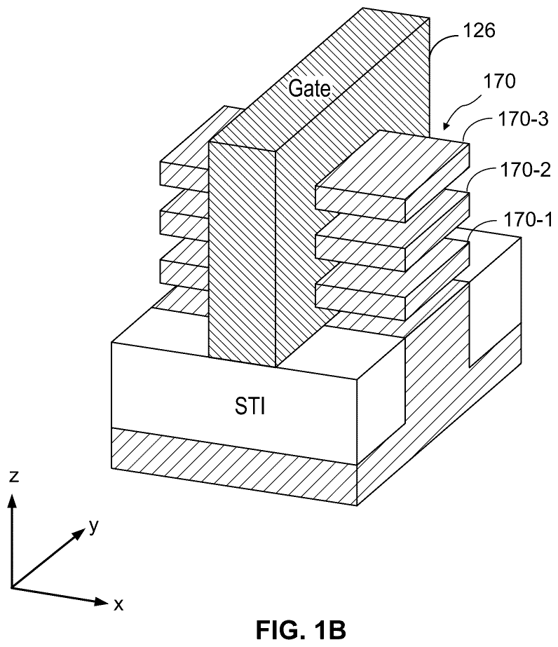

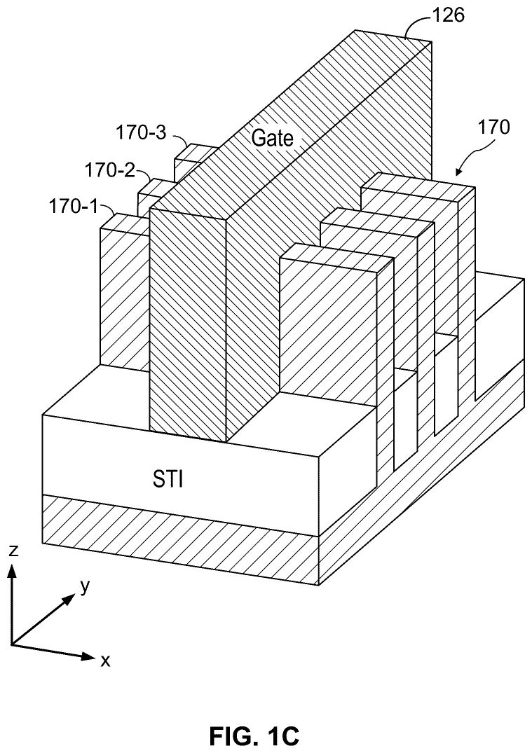

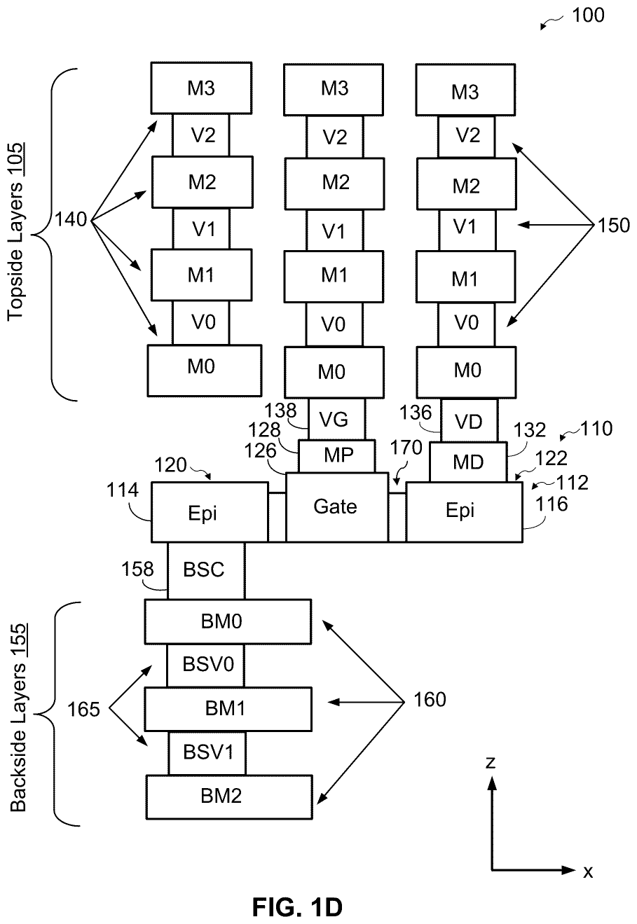

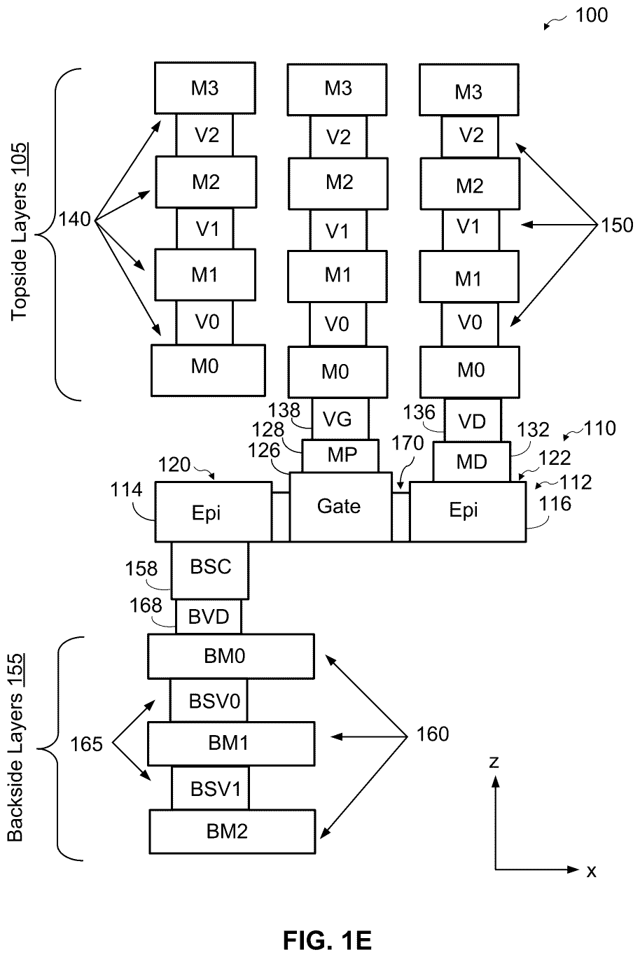

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an active diffusion (RX) or another term. The gate 126 may be formed on the diffusion region 112, and the gate 126 may include a high-k metal gate (HKMG) and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epitaxial (epi) layers may be coupled to opposite sides of the one or more channels 170, as discussed further below.

For the example of a gate-all-around FET process, the gate 126 may surround each of the one or more channels 170 (also referred as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In certain aspects, the chip 100 may include shallow trench isolation (STI) to reduce leakage between active devices on the chip 100. However, the STI may be omitted in some implementations.

For the example of a FinFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail provides a supply voltage Vdd and may also be referred to as a power rail, a positive supply rail, a Vdd rail, or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 (labeled “VG”) disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In these implementations, the via 138 may make direct contact with the gate 126. In this example, the chip 100 also includes a via 134 (labeled “VD”) disposed between the contact 130 and metal layer M0, in which the via 134 couples the contact 130 to metal layer M0. The chip 100 also includes a via 136 (labeled “VD”) disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to provide a circuit (e.g., an inverter, a driver, a logic gate, combinational logic, a latch, a flip-flop, a bit cell (e.g., a static random-access memory (SRAM) bit cell), or another type of circuit. The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell defined in the standard cell library may also be referred to as a standard cell.

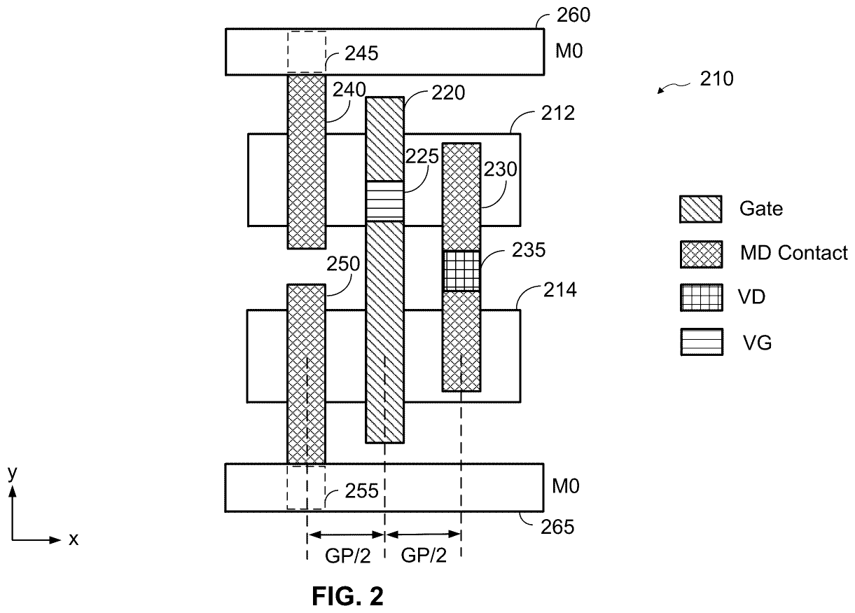

FIG. 2 shows a top view of an exemplary structure 210 on the chip 100 according to certain aspects. The structure 210 may be in a standard cell in some implementations. In this example, the structure 210 includes a first diffusion region 212 and a second diffusion region 214 extending in the x direction. As discussed above, a diffusion region may also be referred to as an active region (RX) or another term. For ease of illustration, the diffusion regions 212 and 214 are shown as rectangles in FIG. 2. The diffusion regions 212 and 214 may be isolated from the diffusion regions of adjacent cells (not shown) by diffusion breaks (not shown).

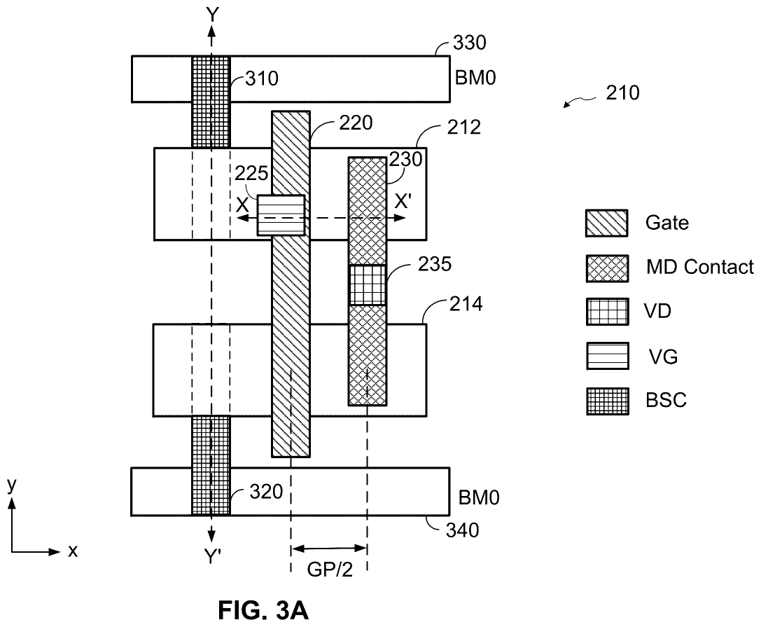

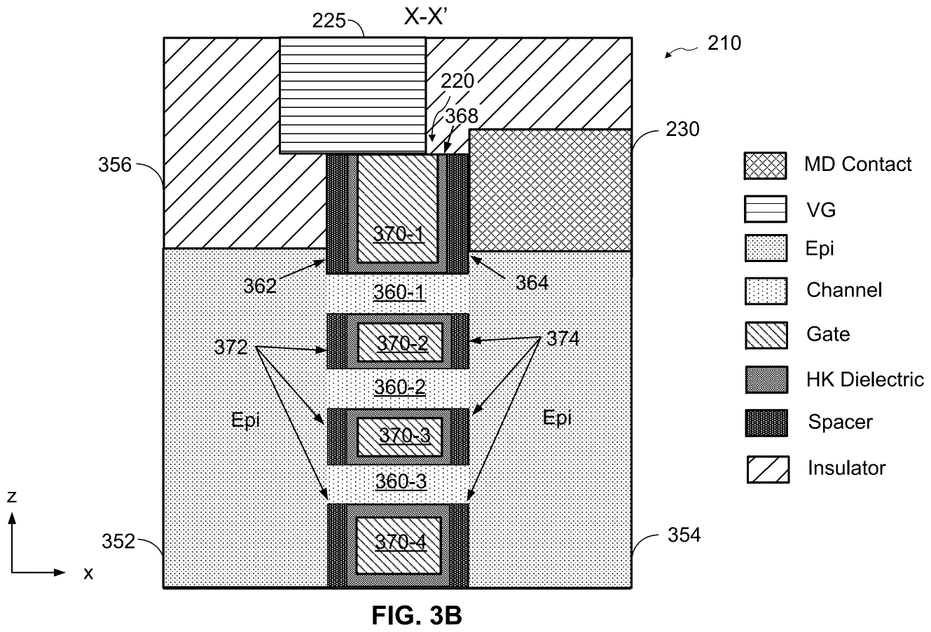

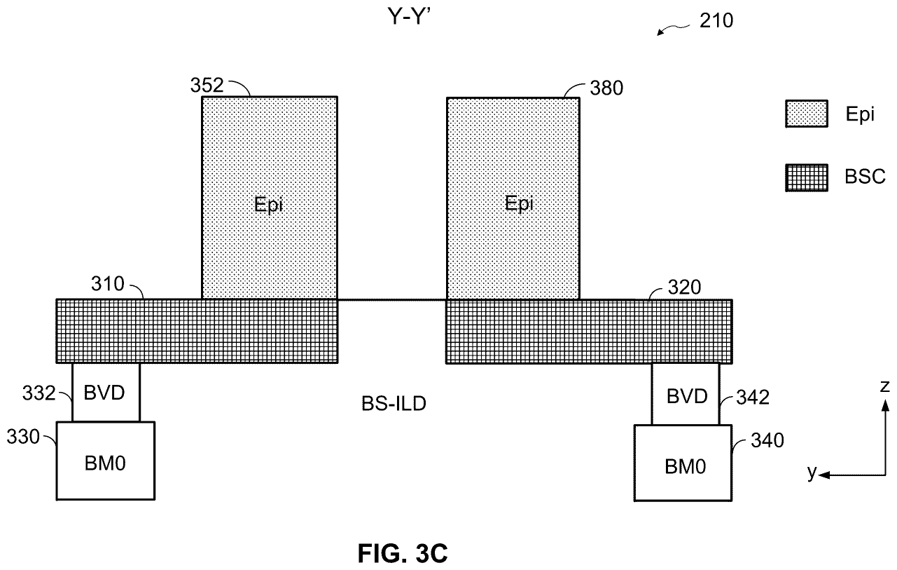

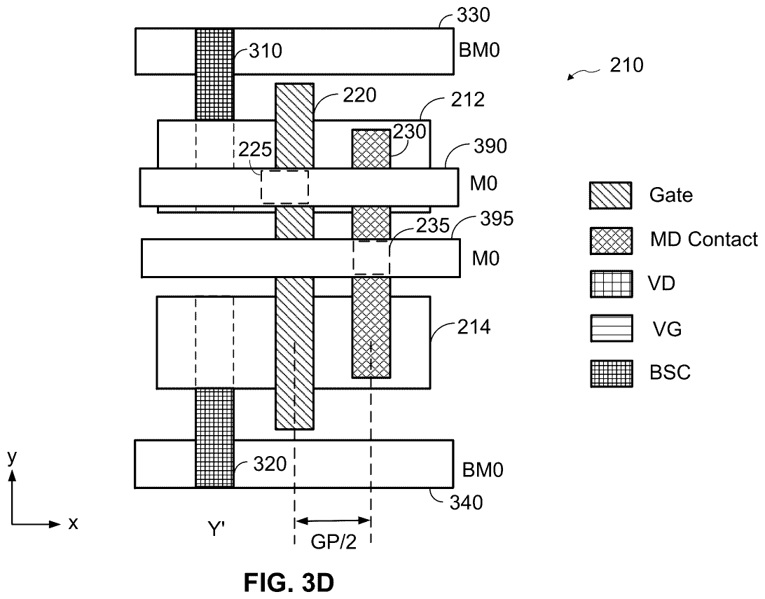

The first diffusion region 212 may include one or more channels extending in the x direction (e.g., the one or more channels 170) and one or more epi layers (e.g., the epi layers 114 and 116). Also, the second diffusion region 214 may include one or more channels extending in the x direction (e.g., the one or more channels 170) and one or more epi layers (e.g., the epi layers 114 and 116). Each channel may include a nanosheet, a nanowire, or another type of channel. Examples of epi layers and channels are shown in FIG. 3B.

In this example, the structure 210 also includes a gate 220 extending in the y direction over the diffusion regions 212 and 214. The gate 220 may include a high-k metal gate and/or another gate material. It is to be appreciated that the structure 210 is not limited to the number of gates shown in the example in FIG. 2, and that the structure 210 may include multiple gates (e.g., multiple gates spaced apart in the x direction by a uniform pitch) in some implementations. The gate 220 and the first diffusion region 212 may form a p-type field effect transistor (PFET) and the gate 220 and the second diffusion region 214 may form an n-type field effect transistor (NFET), or vice versa. However, it is to be appreciated that the present disclosure is not limited to this example.

The structure 210 also includes a gate coupling structure 225 disposed on the gate 220. The gate coupling structure 225 may include a via (e.g., VG in FIGS. 1A, 1D, and 1E) and/or a gate contact. The gate coupling structure 225 is used to couple the gate 220 to signal routing (not shown) in metal layer M0.

FIG. 2 also shows an example of a first rail 260 and a second rail 265 formed in metal layer M0. In this example, the first rail 260 may be a supply rail and the second rail 265 may be a ground rail, or vice versa. A ground rail may also be referred to as a Vss rail, a negative supply rail, or another term.

The structure 210 also includes a frontside contact 240 (e.g., MD contact in FIGS. 1A, 1D, and 1E) extending in the y direction and deposed on a top surface of the first diffusion region 212. The structure 210 also includes a via 245 (e.g., VD in FIGS. 1A, 1D, and 1E) deposed between a top surface of the contact 240 and the first rail 260. In this example, the contact 240 and the via 245 are used to couple a first source/drain of the first diffusion region 212 to the first rail 260.

The structure 210 also includes a frontside contact 250 (e.g., MD contact in FIGS. 1A, 1D, and 1E) extending in the y direction and deposed on a top surface of the second diffusion region 214. The structure 210 also includes a via 255 (e.g., VD in FIGS. 1A, 1D, and 1E) deposed between a top surface of the contact 250 and the second rail 265. In this example, the contact 250 and the via 255 are used to couple a first source/drain of the second diffusion region 214 to the second rail 265.

The structure 210 also includes a frontside contact 230 (e.g., MD contact in FIGS. 1A, 1D, and 1E) extending in the y direction and deposed on a top surface of the first diffusion region 212 and a top surface of the second diffusion region 214. The structure 210 also includes a via 235 (e.g., VD in FIGS. 1A, 1D, and 1E) deposed on a top surface of the contact 230. In this example, the contact 230 and the via 235 are used to couple a second source/drain of the first diffusion region 212 and a second source/drain of the second diffusion region 214 to signal routing (not shown) in metal layer M0.

FIG. 2 shows an example of frontside power distribution in which power is distributed to the first source/drain of the first diffusion region 212 and the first source/drain of the second diffusion region 214 through the frontside contacts 240 and 250. In the example in FIG. 2, the gate coupling structure 225 (e.g., VG in FIGS. 1A, 1D, and 1E) is located between the frontside contact 240 and the frontside contact 230 in the x direction. As a result, the gate coupling structure 225 has frontside contacts (i.e., the frontside contacts 240 and 230) on both sides. In this example, the gate coupling structure 225 and the gate 220 are symmetric which provides equal spacing between the gate coupling structure 225 and each of the contacts 240 and 230. In the example shown in FIG. 2, the spacing is half a gate pitch (GP) which is the pitch between the adjacent gates in the x direction. A challenge is that the spacing is becoming increasingly tight in advanced process nodes. The tight spacing can cause the gate coupling structure 225 to short with one or both of the contacts 230 and 240 due to process variation leading to lower yields.

FIG. 3A shows a top view of an example in which backside power distribution is used to provide power instead of the frontside power distribution illustrated in FIG. 2. In the example in FIG. 3A, the structure 210 includes the first diffusion region 212, the second diffusion region, the gate 220, the frontside contact 230, and the via 235 discussed above with reference to FIG. 2. In this example, the structure 210 also includes a first backside contact 310, a second backside contact 320, a first backside rail 330, and a second backside rail 340 for backside power distribution according to certain aspects.

In this example, the backside rails 330 and 340 are formed in backside metal layer BM0 and extend in the x direction. The first backside rail 330 may be a supply rail and the second backside rail 340 may be a ground rail, or vice versa.

In this example, the first backside contact 310 (e.g., BSC in FIGS. 1D and 1E) is disposed on a backside (i.e., bottom) surface of the first diffusion region 212 and extends over the first backside rail 330. The first backside contact 310 is coupled to the first backside rail 330 to provide power routing for the first source/drain of the first diffusion region 212.

The second backside contact 320 (e.g., BSC in FIGS. 1D and 1E) is disposed on a backside (i.e., bottom) surface of the second diffusion region 214 and extends over the second backside rail 340. The second backside contact 320 is coupled to the second backside rail 340 to provide power routing for the first source/drain of the second diffusion region 214.

In the example in FIG. 3A, the frontside contacts 240 and 250 to the left of the gate coupling structure 225 in FIG. 2 are omitted. This is because power is routed from the backside through the backside contacts 310 and 320. The removal of the frontside contacts 240 and 250 allows the gate coupling structure 225 to be shifted to the left without the risk of shorting to the frontside contact 240. Shifting the gate coupling structure 225 to the left increases the process margin between the gate coupling structure 225 and the frontside contact 230 (which is located to the right of the gate coupling structure 225 in this example), and therefore improves yield.

The removal of the frontside contacts 240 and 250 also allow the gate coupling structure 225 to be elongated in the x direction. The elongation of the gate coupling structure 225 reduces the resistance in the gate coupling structure 225, which reduces power dissipation in the gate coupling structure 225 for improved power efficiency.

FIG. 3B shows a cross-section view of the structure 210 taken along the cross-section line X-X′ in FIG. 3A, which runs in the x direction and intersects the first diffusion region 212 and the gate 220. In this example, the first diffusion region 212 includes a first epi layer 352 and a second epi layer 354 in which the gate 220 is disposed between the first epi layer 352 and the second epi layer 354. The first epi layer 352 provides the first source/drain of the first diffusion region 212 discussed above and the second epi layer 354 provides the second source/drain of the first diffusion region 212 discussed above. In this example, the frontside contact 230 is disposed on the top surface of the second epi layer 354. The chip 100 may include an epi block layer (not shown) under the epi layers 352 and 354.

In this example, the first diffusion region 212 also includes one or more channels 360-1 to 360-3 passing through the gate 220 and coupled between the first epi layer 352 and the second epi layer 354. The one or more channels 360-1 to 360-3 may include nanosheets, nanowires, or other types of channels.

The gate 220 may include gate metal 370-1 to 370-4 and a thin dielectric 368 (e.g., high-k (HK) dielectric) surrounding the gate metal 370-1 to 370-4, as shown in the example in FIG. 3B. It is to be appreciated that the gate metal 370-1 to 370-4 may include multiple types of metals in some implementations. In this example, the one or more channels 360-1 to 360-3 pass through the gate 220.

The structure 210 may also include first inner spacers 372 between the gate 220 and the first epi layer 352, and second inner spacers 374 between the gate 220 and the second epi layer 354. The structure 210 may also include spacers 362 and 364 on opposite sides of a top portion of the gate 220 (e.g., to help isolate the gate 220 from frontside contacts (e.g., the frontside contact 230)). The spacers 362 and 364 may also be called sidewall spacers or another term.

The structure 210 also include an insulator 356 over the first epi layer 352 and the frontside contact 230. The insulator 356 may include silicon oxide and/or another dielectric. The insulator 356 may also be referred to as an insulating layer, an interlayer dielectric (ILD), or another term.

In the example in FIG. 3B, the gate coupling structure 225 (e.g., VG in FIGS. 1A, 1D, and 1E) is disposed on the top surface of the gate 220 and may be shifted to the left with respect to the position of the gate coupling structure 225 in FIG. 2. Shifting the gate coupling structure 225 to the left increases the process margin between the gate coupling structure 225 and the frontside contact 230 in this example, as discussed above.

In the example in FIG. 3B, the frontside contact 230 is located to the right of the gate 220 and the gate coupling structure 225 is shifted to the left to increase the process margin between the gate coupling structure 225 and the frontside contact 230. However, it is to be appreciated that the structure 210 is not limited to this example. In another example, the frontside contact 230 may be located to the left of the gate 220 with the gate coupling structure 225 shifted to the right to increase the process margin between the gate coupling structure 225 and the frontside contact 230.

In the example in FIG. 3B, the gate coupling structure 225 extends over a portion of the first epi layer 352 in the x direction. This extension allows the gate coupling structure 225 to be elongated in the x direction, which reduces the resistance in the gate coupling structure 225, as discussed above. In this example, a portion of the insulator 356 is deposed between the gate coupling structure 225 and the top surface of the first epi layer 352, which helps electrically isolate the gate coupling structure 225 from the first epi layer 352.

FIG. 3C shows a cross-section view of the structure 210 taken along the cross-section line Y-Y′ in FIG. 3A, which runs in the y direction and intersects the backside contacts 310 and 320 and the backside rails 330 and 340. As shown in FIG. 3C, the first backside contact 310 (e.g., BSC in FIGS. 1D and 1E) is disposed on a backside (i.e., bottom) surface of the first epi layer 352 and extends over the first backside rail 330. The first backside contact 310 is coupled to the first backside rail 330 through backside via 332 (e.g., BVD in FIG. 1E) to provide power routing for the first source/drain of the first diffusion region 212. In the example in FIG. 3C, the first backside contact 310 is coupled to the first backside rail 330 through the backside via 332. In other implementations, the first backside contact 310 may be coupled directly to the first backside rail 330.

In the example in FIG. 3C, the second backside contact 320 (e.g., BSC in FIGS. 1D and 1E) is disposed on a backside (i.e., bottom) surface of an epi layer 380 of the second diffusion region 214 and extends over the second backside rail 340. In this example, the epi layer 380 provides the first source/drain of the second diffusion region 214 discussed above. The second backside contact 320 is coupled to the second backside rail 340 through backside via 342 (e.g., BVD in FIG. 1E) to provide power routing for the first source/drain of the second diffusion region 214. In the example in FIG. 3C, the second backside contact 320 is coupled to the second backside rail 340 through the backside via 342. In other implementations, the second backside contact 320 may be coupled directly to the second backside rail 340.

The structure 210 also includes a backside interlayer dielectric (BS-ILD) between the backside contacts 310 and 320 and between the backside rails 330 and 340. The backside contacts 310 and 320, the backside rails 330 and 340, and the BS-ILD 345 may be formed during backside processing after removal of the substrate (e.g., substrate 108 in FIG. 1A). The BS-ILD may include silicon oxide, silicon nitride, silicon carbon oxynitride (SiCON), or another dielectric material.

FIG. 3D shows a top view of an example of a first signal route 390 and a second signal route 395 formed in metal layer M0 and extending in the x direction. In this example, the gate coupling structure 225 is coupled between the gate 220 and the first signal route 390 to provide signal routing for the gate 220. The via 235 is coupled between the frontside contact 230 and the second signal route 395 to provide signal routing for the second source/drain of the first diffusion region 212 and the second source/drain of the second diffusion region 214.

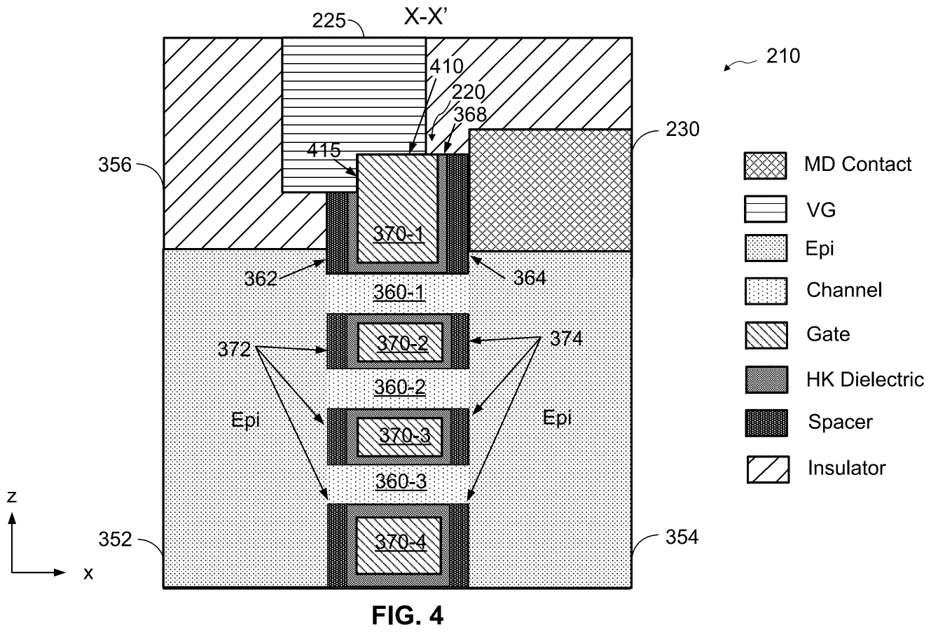

FIG. 4 shows a cross-sectional view of another example of the gate coupling structure 225 taken along the cross-section line X-X′ in FIG. 3A. In this example, the gate coupling structure 225 contacts a top surface 410 of the gate 220 and a side surface 415 of the gate 220. The contact with the side surface 415 increases the contact area between the gate coupling structure 225 and the gate 220, which reduces the contact resistance between the gate 220 and the gate coupling structure 225 (e.g., VG in FIGS. 1A, 1D, and 1E). In the example in FIG. 4, the top surface 410 is a top surface of the gate metal 370-1 and the side surface 415 is a side surface of the gate metal 370-1. As discussed above, the gate metal 370-1 may include multiple metal layers in some implementations.

In this example, a portion of the spacer 362 and a portion of the dielectric 368 (e.g., HK dielectric) between the spacer 362 and the gate metal 370-1 are etched away to expose the side surface 415 for contact with the gate coupling structure 225. An example of the etching process is discussed further below.

In the example shown in FIG. 4, the side surface 415 is on the left side of the gate 220. However, it is to be appreciated that, in other implementations, the side surface 415 may be on the right side of the gate 220 with the frontside contact 230 located to the left of the gate 220. In general, the side surface 415 is opposite to the side of the gate 220 adjacent to the frontside contact 230.

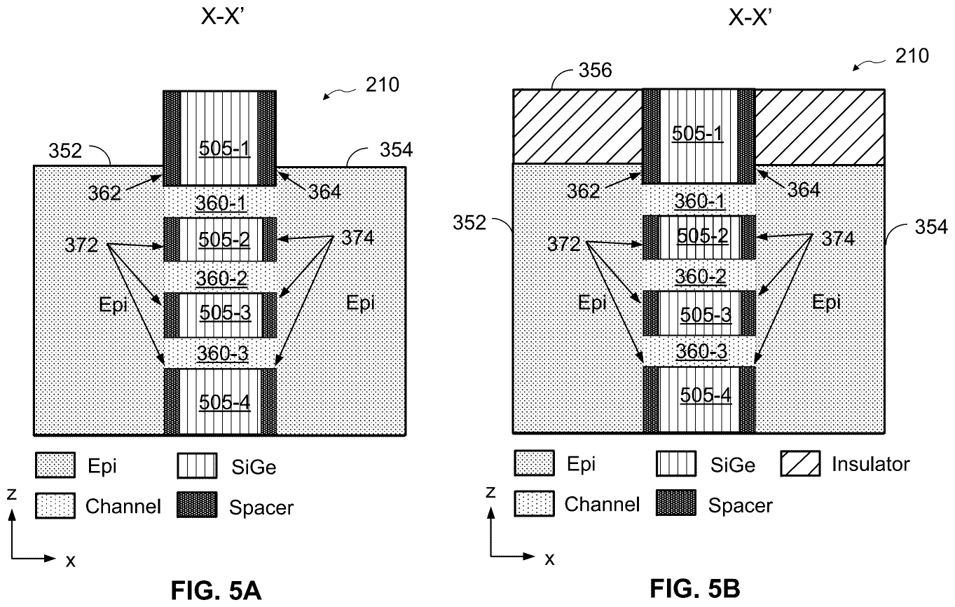

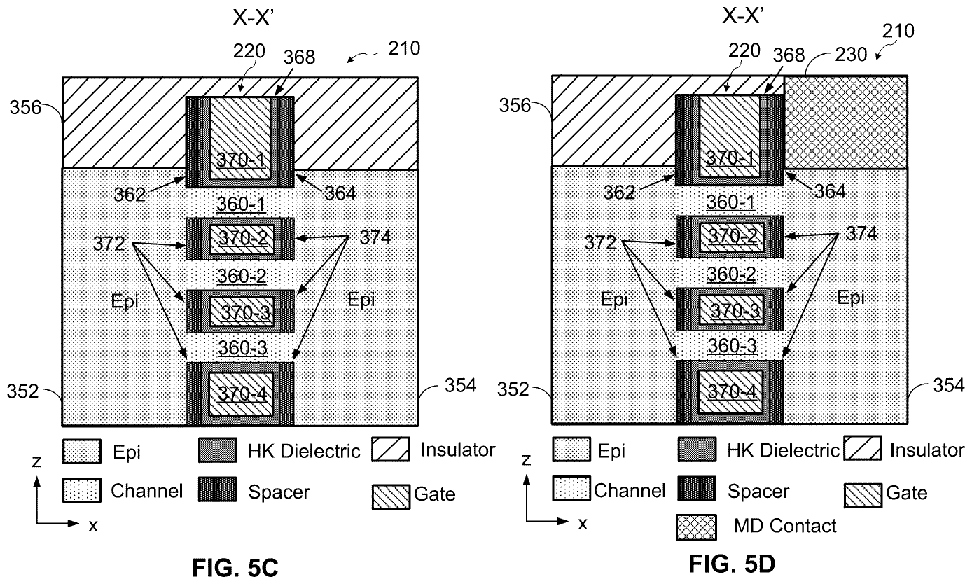

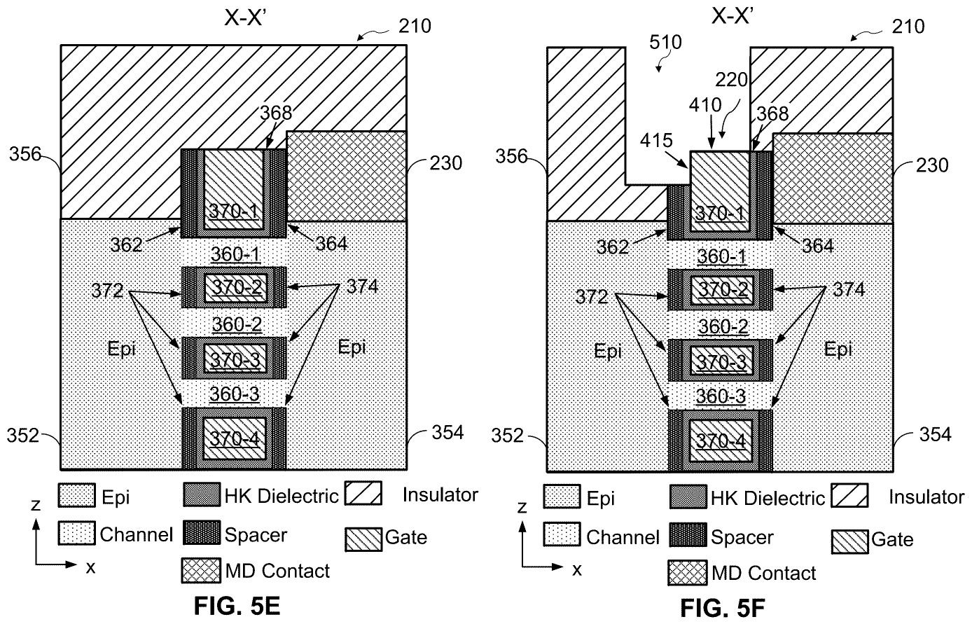

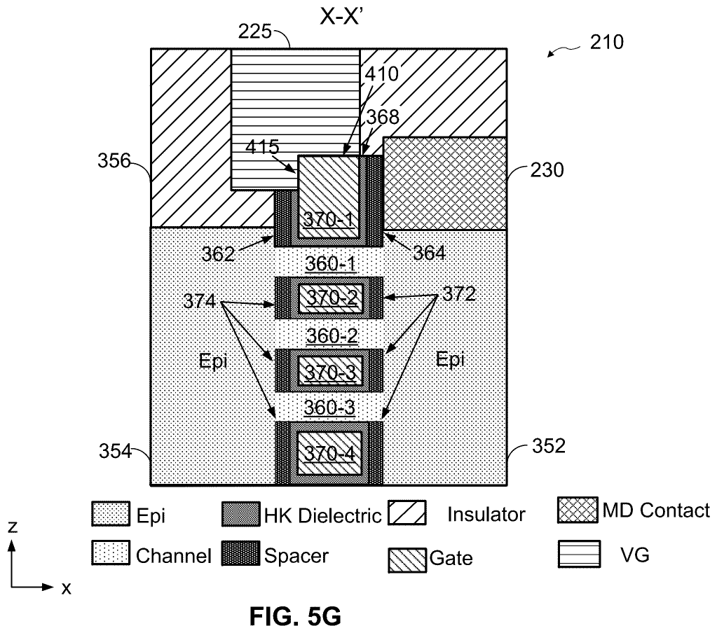

An exemplary frontside process for forming the exemplary structure 210 in FIG. 4 will now be described with reference to FIGS. 5A to 5G according to certain aspects. FIGS. 5A to 5G show the cross-sectional view of the exemplary structure 210 taken along the cross-section line X-X′ at different stages during the processing. Examples of etching processes that may be used in one or more of the stages discussed below include plasma etching, reactive-ion etching, wet etching, isotropic etching, or any combination thereof.

FIG. 5A shows an example after formation of the first epi layer 352 and the second epi layer 354. As this stage, the structure 210 includes sacrificial layers 505-1 to 505-4 between the channels 360-1 to 360-3. The sacrificial layers 505-1 to 505-4 are released at a later stage and replaced with the gate metal 370-1 to 370-4, as discussed further below. In certain aspects, the sacrificial layers 505-1 to 505-4 include silicon germanium (SiGe) and/or another material. The channels 360-1 to 360-3 may include silicon and/or another material.

In FIG. 5B, insulating material is deposited on the chip 100 to form the insulator 356. The portion (not shown) of the insulator above the gate 220 may be removed using, for example, chemical mechanical polishing (CMP) and/or another technique. The insulator 356 may include silicon oxide (SiO2) and/or another insulating material.

FIG. 5C illustrates a replacement metal gate (RMG) process in which the sacrificial layers 505-1 to 505-4 are released and replaced with the gate metal 370-1 to 370-4 and the dielectric 368 (e.g., HK dielectric). During the RMG process, the release of the sacrificial layers 505-1 to 505-4 creates a recess (not shown) between the spacers 362 and 364 and cavities between the inner spacers 372 and 374. The recess and the cavities are then filled with the gate metal 370-1 to 370-4 and the dielectric 368 to form the gate 220. After formation of the gate 220, additional insulating material (e.g., SiO2) may be deposited, which increases the height of the insulator 356.

FIG. 5D illustrates formation of the frontside contact 230 (e.g., MD in FIGS. 1A, 1D, and 1E). In this example, a portion of the insulator 356 is etched away to form a hole exposing a top surface of the second epi layer 354. The hole is then filled with a conductive material to form the frontside contact 230, as shown in FIG. 5D.

In FIG. 5E, additional insulating material (e.g., SiO2) is deposited, which increases the height of the insulator 356.

In FIG. 5F, a hole 510 is etched in the insulator 356 to expose the top surface 410 of the gate 220. In addition, a portion of the spacer 362 and the dielectric 368 (e.g., HK dielectric) are etched away to expose the side surface 415 of the gate 220.

In FIG. 5G, the hole 510 is filled with a conductive material to form the gate coupling structure 225 (e.g., VG in FIGS. 1A, 1D, and 1E).

After formation of the gate coupling structure 225, the remaining frontside processing may be performed including formation of the topside layers 105 (e.g., the signal routes 390 and 395 in metal layer M0). After the frontside processing, a carrier wafer (not shown) may be bonded to the top of the chip 100 for structural support. The chip 100 may then be flipped to expose the backside of the semiconductor substrate 108. The semiconductor substrate 108 may then be removed in multiple steps which may include grinding, chemical mechanical polishing (CMP)), etching, and wet cleaning. After removal of the substrate 108, the backside layers 155 may be formed including the backside contacts 310 and 320 and the backside rails 330 and 340 shown in FIG. 3C.

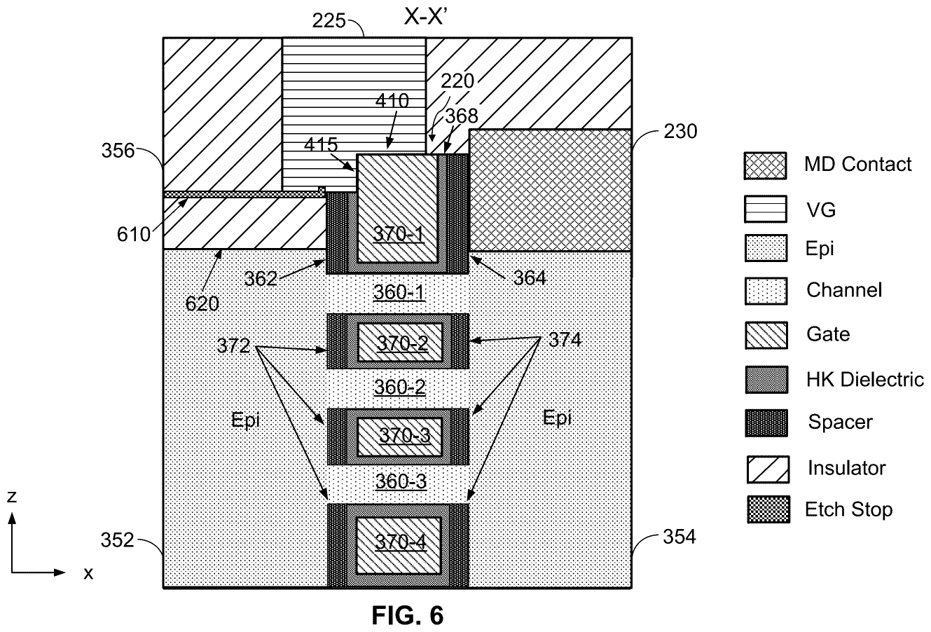

FIG. 6 shows a cross-sectional view of another example of the structure 210 taken along the cross-section line X-X′ in FIG. 3A. In this example, the structure 210 also includes an etch stop layer 610 to prevent over etching of the insulator 356 when creating the hole 510 for the gate coupling structure 225. In other words, the etch stop layer 610 blocks the hole 510 from reaching the first epi layer 352 due to over etching and shorting the gate coupling structure 225 and the first epi layer 352. The etch stop layer 610 may include a material (e.g., silicon nitride (SiN)) that etches at a much slower rate than the insulator 356 during the etching process used to form the hole 510 (i.e., the etch selectivity for the insulator 356 is high compared with the etch stop layer 610). In the example shown in FIG. 6, the etch stop layer 610 protects the portion 620 of the insulator 356 between the etch stop layer 610 and the first epi layer 352 from over etching.

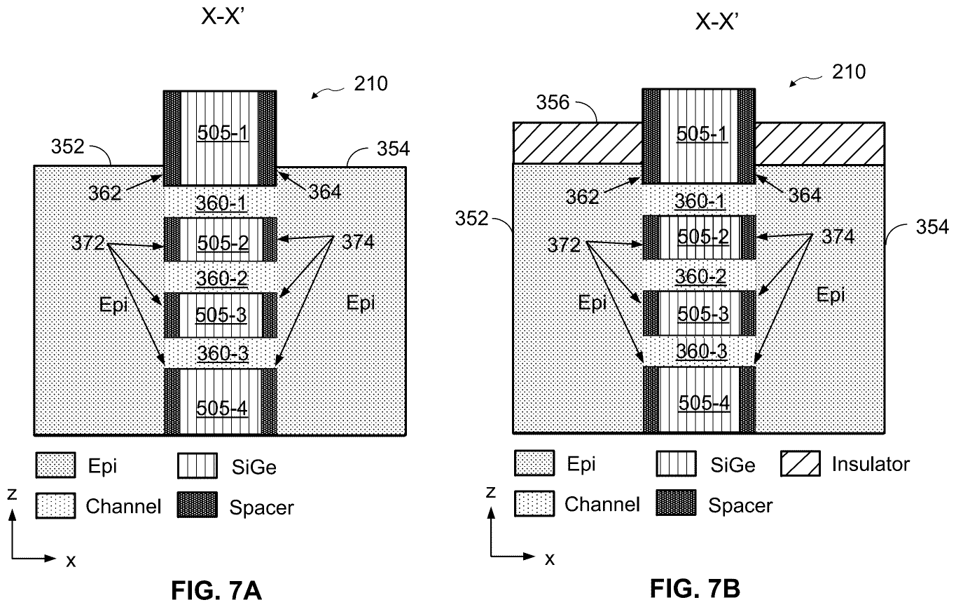

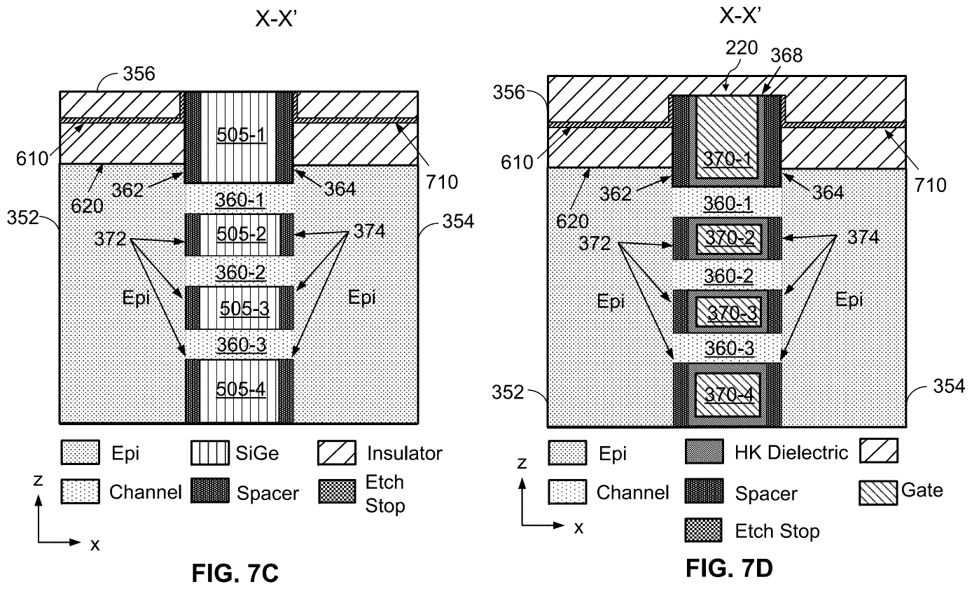

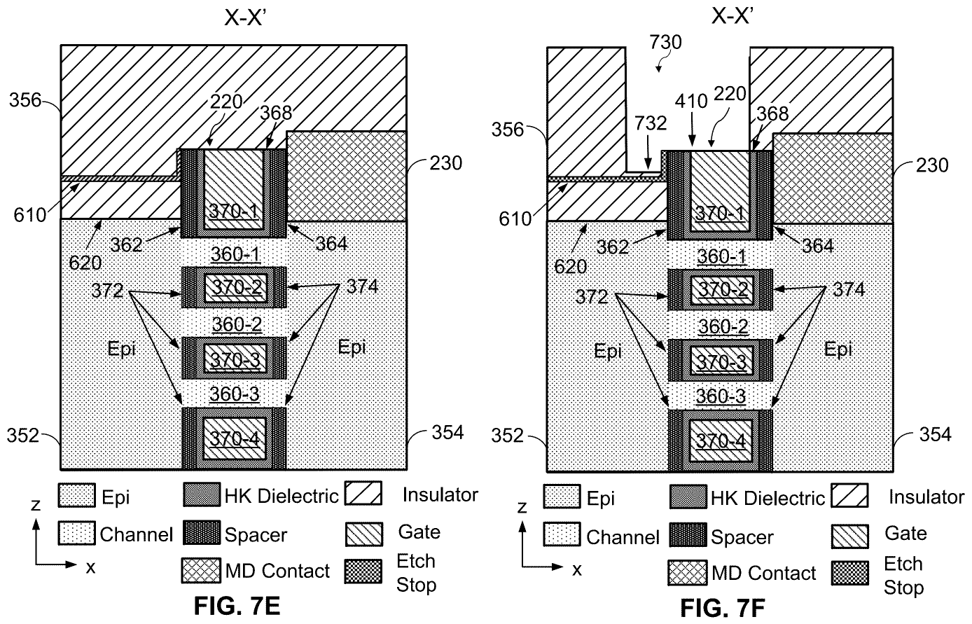

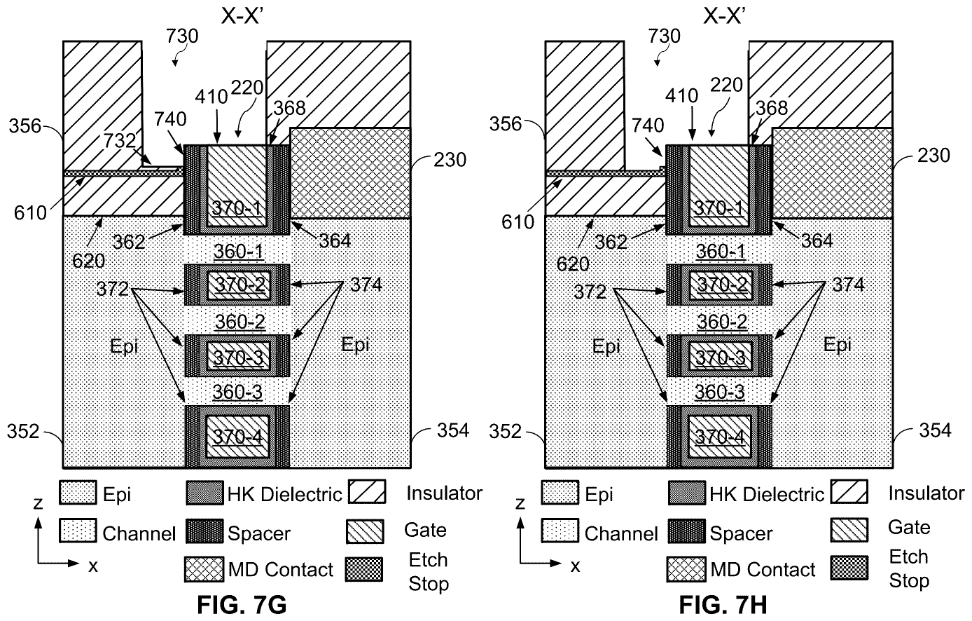

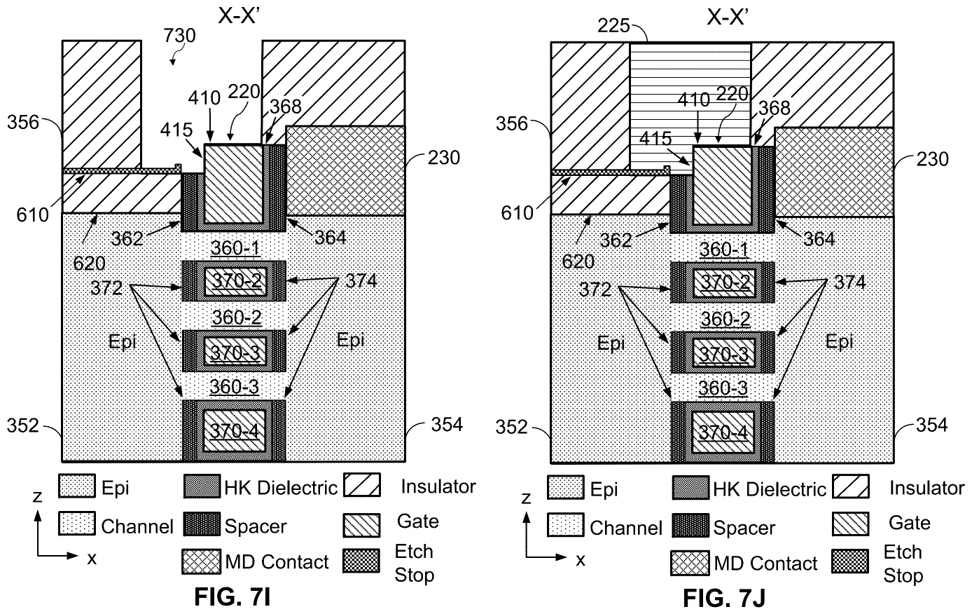

An exemplary frontside process for forming the exemplary structure 210 in FIG. 6 will now be described with reference to FIGS. 7A to 7J according to certain aspects. FIGS. 7A to 7J show the cross-sectional view of the exemplary structure 210 taken along the cross-section line X-X′ at different stages during the processing. Examples of etching processes that may be used in one or more of the stages discussed below include plasma etching, reactive-ion etching, wet etching, isotropic etching, or any combination thereof.

FIG. 7A shows an example after formation of the first epi layer 352 and the second epi layer 354. As this stage, the structure 210 includes the sacrificial layers 505-1 to 505-4 discussed above with reference to FIG. 5A.

In FIG. 7B, insulating material is deposited on the chip 100 to form the insulator 356. In this example, a portion (not shown) of the insulator 356 may be etched away to lower the top of the insulator 356 below the tops of the spacers 362 and 264, as shown in FIG. 7B.

In FIG. 7C, the etch stop material (e.g., SiN) is deposited on the insulator 356 and the sides of the spacers 362 and 364 to form the etch stop layer 610. In the example in FIG. 7C, the deposition of the etch stop material also forms a second etch stop layer 710. As discussed further below, the second etch stop layer 710 may be removed during formation of the frontside contact 230. After formation of the etch stop layer 610, additional insulating material is deposited over the etch stop layer 610 to increase the height of the insulator 356. In certain aspects, the insulator 356 may be polished (e.g., using CMP) to make the top of the insulator 356 flush with the tops of the spacers 362 and 264, as shown in the example in FIG. 7C.

FIG. 7D illustrates an RMG process in which the sacrificial layers 505-1 to 505-4 are released and replaced with the gate metal 370-1 to 370-4 and the dielectric 368 (e.g., HK dielectric). During the RMG process, the release of the sacrificial layers 505-1 to 505-4 creates a recess (not shown) between the spacers 362 and 364 and cavities between the inner spacers 372 and 374. The recess and the cavities are then filled with the gate metal 370-1 to 370-4 and the dielectric 368 to form the gate 220. After formation of the gate 220, additional insulating material (e.g., SiO2) may be deposited, which increases the height of the insulator 356, as shown in FIG. 7D.

FIG. 7E illustrates formation of the frontside contact 230 (e.g., MD in FIGS. 1A, 1D, and 1E). In this example, a portion of the insulator 356 and the etch stop layer 710 are removed to form a hole exposing a top surface of the second epi layer 354. The hole is then filled with a conductive material to form the frontside contact 230, as shown in FIG. 7E. After formation of the frontside contact 230, additional insulating material (e.g., SiO2) is deposited, which increases the height of the insulator 356.

In FIG. 7F, a hole 730 is etched in the insulator 356 to expose the top surface 410 of the gate 220. The hole 730 also extends downward to the left of the gate 220. In this example, the etch stop layer 610 acts as a barrier for the etching process used to etch the insulator 356. In the example shown in FIG. 7F, a thin layer 732 of the insulator 356 is left to protect the portion of the etch stop layer 610 below the thin layer 732 during etching of the sidewall of the etch stop layer 610, as discussed further below.

In FIG. 7G, the sidewall of the etch stop layer 610 on the side of the gate 220 is etched away to expose the side surface 740 of the spacer 362. For example, the sidewall of the etch stop layer 610 may be etched away in the x direction using isotropic etching. In this example, the thin layer 732 of the insulator 356 (e.g., SiO2) protects the portion of the etch stop layer 610 below the thin layer 732 from the etching.

In FIG. 7H, the etching of the hole 730 is completed in preparation for the formation of the gate coupling structure 225. This includes etching away the thin layer 732 of the insulator 356. In this example, the etch stop layer 610 protects the portion of the insulator 356 (e.g., SiO2) below the etch stop layer 610 from the etching.

In FIG. 7I, a portion of the spacer 362 and the dielectric 368 (e.g., HK dielectric) are etched away to expose the side surface 415 of the gate 220. The etching creates a notch (i.e., opening) in the spacer 362 exposing the side surface 415 of the gate 220. The notch may have an approximately rectangular shape in the y and z directions.

In FIG. 7J, the hole 730 is filled with a conductive material to form the gate coupling structure 225 (e.g., VG in FIGS. 1A, 1D, and 1E). The gate coupling structure 225 contacts the stop surface 222 of the gate 220 and contacts the side surface 415 of the gate 220 through the notch (i.e., opening) in the spacer 362.

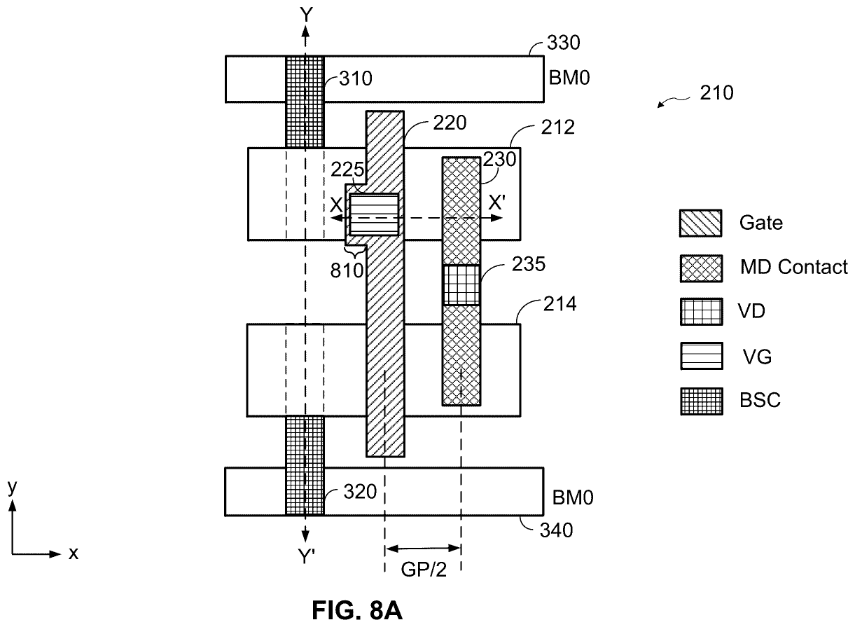

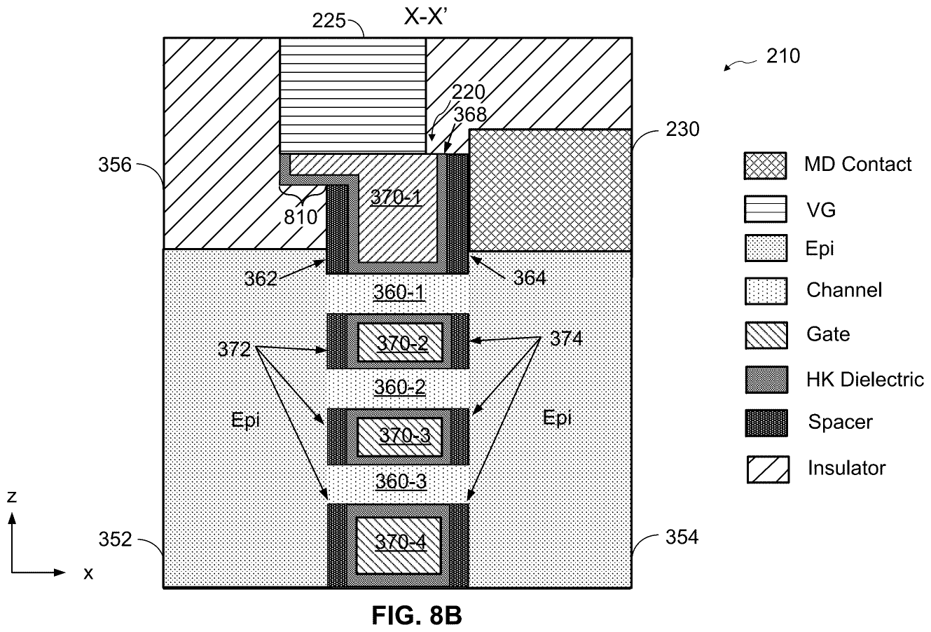

FIG. 8A shows a top view of an example of the gate 220 in which the gate 220 includes a ledge 810 that extends from a side of the gate 220. In the example shown in FIG. 8A, the ledge 810 extends from the left side of the gate 220. However, it is to be appreciated that the present disclosure is not limited to this example. In general, the ledge 810 extends from the side of the gate 220 that is opposite to the side of the gate 220 adjacent to the frontside contact 230. The ledge 810 may also be referred to as a protrusion or another term.

In FIG. 8B shows a cross-sectional view of the ledge 810 taken along the cross-section line X-X′ in FIG. 8A. In this example, the ledge 810 extends over a portion of the first epi layer 352. A portion of the insulator 356 (e.g., SiO2) is deposed between the ledge 810 and the first epi layer 352, which helps electrically isolate the ledge 810 from the first epi layer 352.

As shown in FIGS. 8A and 8B, at least a portion of the gate coupling structure 225 is placed on the ledge 810. Since the ledge 810 extends from the side of the gate 220 that is opposite to the side of the gate 220 adjacent to the frontside contact 230, the ledge 810 allows the gate coupling structure 225 to be shifted away from the frontside contact 230 to increase the process margin between the gate coupling structure 225 and the frontside contact 230.

The ledge 810 allows the gate coupling structure 225 to be elongated in the x direction, which reduces the resistance in the gate coupling structure 225. The ledge 810 also allows the gate coupling structure 225 to make contact with a larger area of the gate 220, which reduces the contact resistance between the gate 220 and the gate coupling structure 225.

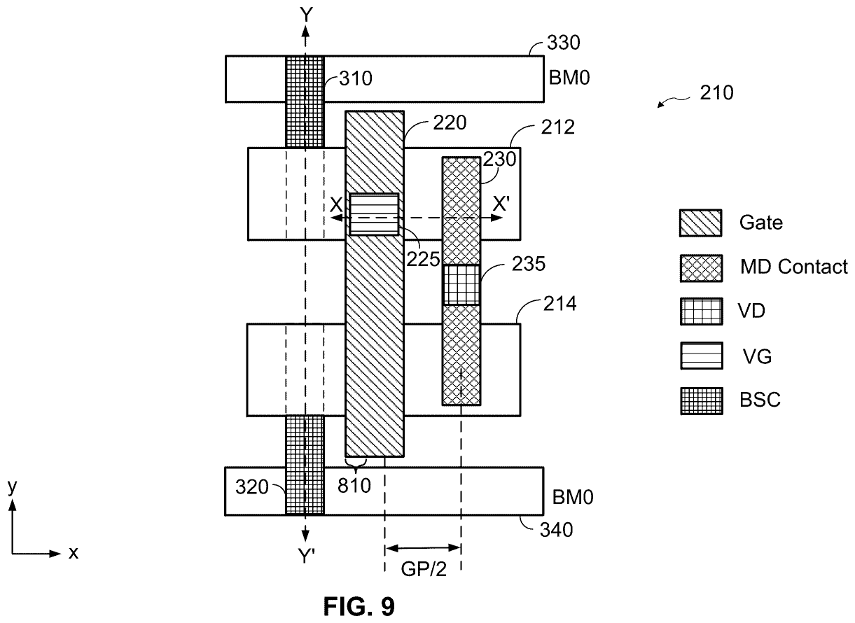

It is to be appreciated that the ledge 810 may extend farther in the y direction than shown in the example in FIG. 8A. In this regard, FIG. 9 shows an example in which the ledge 810 extends the entire length of the gate 220 in the y direction, which provides flexibility in the placement of the gate coupling structure 225 in the y direction.

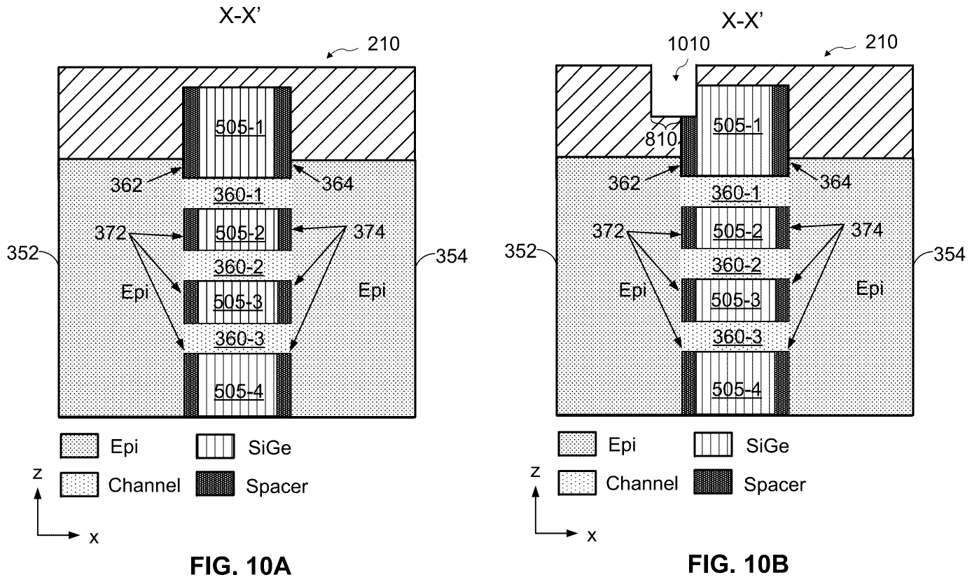

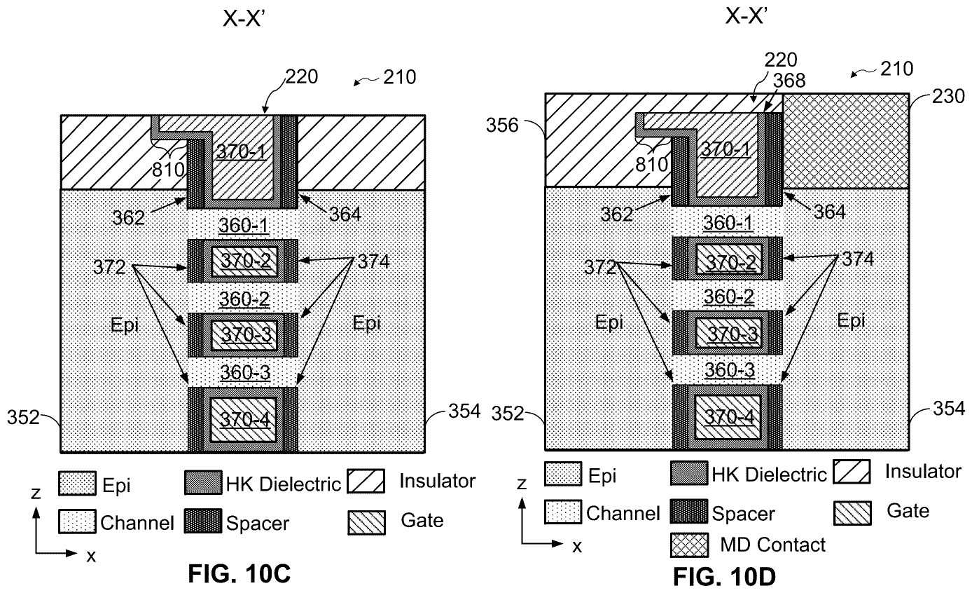

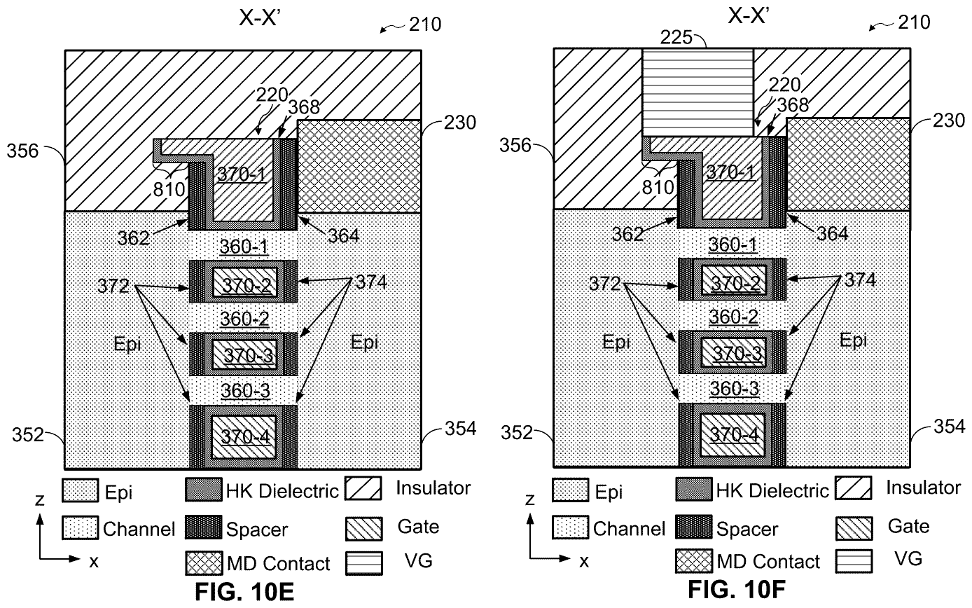

An exemplary frontside process for forming the ledge 810 will now be described with reference to FIGS. 10A to 10F according to certain aspects. FIGS. 10A to 10F show the cross-sectional view of the exemplary structure 210 taken along the cross-section line X-X′ at different stages during the processing.

FIG. 10A shows an example after formation of the first epi layer 352 and the second epi layer 354. As this stage, the structure 210 includes the sacrificial layers 505-1 to 505-4 discussed above with reference to FIG. 5A.

In FIG. 10B, a portion of the insulator 356 and a portion of the spacer 362 are etched away to form a hole 1010. As discussed further below, the hole 1010 is used to form the ledge 810 during the RMG process.

FIG. 10C illustrates the RMG process in which the sacrificial layers 505-1 to 505-4 are released and replaced with the gate metal 370-1 to 370-4 and the dielectric 368 (e.g., HK dielectric). During the RMG process, the release of the sacrificial layers 505-1 to 505-4 creates a recess (not shown) between the spacers 362 and 364 and cavities between the inner spacers 372 and 374. The recess and the cavities are then filled with the gate metal 370-1 to 370-4 and the dielectric 368 to form the gate 220. As shown in FIG. 10C, the gate metal 370-1 and the dielectric 368 also fill the hole 1010 shown in FIG. 10B to form the ledge 810. After formation of the gate 220 including the ledge 810, additional insulating material (e.g., SiO2) may be deposited, which increases the height of the insulator 356.

FIG. 10D illustrates formation of the frontside contact 230 (e.g., MD in FIGS. 1A, 1D, and 1E). In this example, a portion of the insulator 356 is etched away to form a hole exposing a top surface of the second epi layer 354. The hole is then filled with a conductive material to form the frontside contact 230, as shown in FIG. 10D.

In FIG. 10E, additional insulating material (e.g., SiO2) is deposited, which increases the height of the insulator 356.

In FIG. 10F, a hole is etched in the insulator 356 to expose the top surface 410 of the gate 220 including the top surface of the ledge 810. The hole is filled with a conductive material to form the gate coupling structure 225 (e.g., VG in FIGS. 1A, 1D, and 1E). As shown in FIG. 10F, a portion of the gate coupling structure 225 is disposed on the ledge 810.

Implementation examples are described in the following numbered clauses:
1. A chip, comprising:
   a first source/drain;
   a second source/drain;
   a gate between the first source/drain and the second source/drain, wherein the gate includes a ledge extending from a first side of the gate;
   one or more channels coupled between the first source/drain and the second source/drain, wherein the one or more channels pass through the gate; and
   a gate coupling structure disposed on the gate.
2. The chip of clause 1, wherein at least a portion of the gate coupling structure is disposed on the ledge.
3. The chip of clause 2, wherein the gate coupling structure comprises a via.
4. The chip of clause 2 or 3, wherein the ledge extends over a portion of the first source/drain.
5. The chip of clause 4, further comprising an insulating layer between the ledge and the portion of the first source/drain.
6. The chip of any one of clauses 1 to 5, wherein the first source/drain comprises a first epitaxial (epi) layer and the second source/drain comprises a second epi layer.
7. The chip of any one of clauses 1 to 6, further comprising a frontside contact disposed on a top surface of the second source/drain, wherein the frontside contact is adjacent to a second side of the gate opposite the first side of the gate.
8. The chip of clause 7, further comprising a first signal route extending over the gate, wherein the gate coupling structure is coupled between the gate and the first signal route.
9. The chip of clause 8, further comprising:
   a second signal route extending over the frontside contact; and
   a via coupled between the frontside contact and the second signal route.
10. The chip of clause 9, wherein the first signal route and the second signal route are in a same metal layer.
11. The chip of any one of clauses 7 to 10, further comprising:
   a backside rail; and
   a backside contact coupled between a bottom surface of the first source/drain and the backside rail.
12. The chip of clause 11, wherein the backside rail is a supply rail.
13. The chip of clause 11, wherein the backside rail is a ground rail.
14. A chip, comprising:
   a first source/drain;
   a second source/drain;
   a gate between the first source/drain and the second source/drain;
   one or more channels coupled between the first source/drain and the second source/drain, wherein the one or more channels pass through the gate; and
   a gate coupling structure contacting a top surface of the gate and a first side of the gate.
15. The chip of clause 14, wherein a portion of the gate coupling structure extends over a portion of the first source/drain.
16. The chip of clause 15, further comprising an insulating layer between the portion of the gate coupling structure and the portion of the first source/drain.
17. The chip of any one of clauses 14 to 16, wherein the gate coupling structure comprises a via.
18. The chip of any one of clauses 14 to 17, wherein the first source/drain comprises a first epitaxial (epi) layer and the second source/drain comprises a second epi layer.
19. The chip of any one of clauses 14 to 18, further comprising a frontside contact disposed on a top surface of the second source/drain, wherein the frontside contact is adjacent to a second side of the gate opposite the first side of the gate.
20. The chip of clause 19, further comprising a first signal route extending over the gate, wherein the gate coupling structure is coupled between the gate and the first signal route.
21. The chip of clause 20, further comprising:
   a second signal route extending over the frontside contact; and
   a via coupled between the frontside contact and the second signal route.
22. The chip of clause 21, wherein the first signal route and the second signal route are in a same metal layer.
23. The chip of any one of clauses 19 to 22, further comprising:
   a backside rail; and
   a backside contact coupled between a bottom surface of the first source/drain and the backside rail.
24. The chip of clause 23, wherein the backside rail is a supply rail.
25. The chip of clause 23, wherein the backside rail is a ground rail.
26. The chip of any one of clauses 14 to 25, further comprising:
   a first spacer adjacent to the first side of the gate, wherein the first spacer has a notch, and the gate coupling structure contacts the first side of the gate through the notch; and
   a second spacer adjacent to a second side of the gate opposite the first side of the gate.
27. A chip, comprising:
   a first source/drain;
   a second source/drain;
   a gate between the first source/drain and the second source/drain;
   one or more channels coupled between the first source/drain and the second source/drain, wherein the one or more channels pass through the gate;
   a gate coupling structure disposed on the gate, wherein a portion of the gate coupling structure extends over a portion of the first source/drain; and
   an insulating layer between the portion of the gate coupling structure and the portion of the first source/drain.
28. The chip of clause 27, wherein the gate coupling structure comprises a via.
29. The chip of clause 27 or 28, wherein the first source/drain comprises a first epitaxial (epi) layer and the second source/drain comprises a second epi layer.
30. The chip of any one of clauses 27 to 29, further comprising a frontside contact disposed on a top surface of the second source/drain.
31. The chip of clause 30, further comprising:
   a backside rail; and
   a backside contact coupled between a bottom surface of the first source/drain and the backside rail.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. At least one of A, B, and C means A, B, C, AB, BC, AC, or ABC.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first source/drain;
a second source/drain;
a gate between the first source/drain and the second source/drain, wherein the gate includes a ledge extending from a first side of the gate;
one or more channels coupled between the first source/drain and the second source/drain, wherein the one or more channels pass through the gate; and
a gate coupling structure disposed on the gate.

2. The chip of claim 1, wherein at least a portion of the gate coupling structure is disposed on the ledge.

3. The chip of claim 2, wherein the gate coupling structure comprises a via.

4. The chip of claim 2, wherein the ledge extends over a portion of the first source/drain.

5. The chip of claim 4, further comprising an insulating layer between the ledge and the portion of the first source/drain.

6. The chip of claim 1, wherein the first source/drain comprises a first epitaxial (epi) layer and the second source/drain comprises a second epi layer.

7. The chip of claim 1, further comprising a frontside contact disposed on a top surface of the second source/drain, wherein the frontside contact is adjacent to a second side of the gate opposite the first side of the gate.

8. The chip of claim 7, further comprising a first signal route extending over the gate, wherein the gate coupling structure is coupled between the gate and the first signal route.

9. The chip of claim 8, further comprising:
a second signal route extending over the frontside contact; and
a via coupled between the frontside contact and the second signal route.

10. The chip of claim 7, further comprising:
a backside rail; and
a backside contact coupled between a bottom surface of the first source/drain and the backside rail.

11. A chip, comprising:
a first source/drain;
a second source/drain;
a gate between the first source/drain and the second source/drain;
one or more channels coupled between the first source/drain and the second source/drain, wherein the one or more channels pass through the gate; and
a gate coupling structure contacting a top surface of the gate and a first side of the gate.

12. The chip of claim 11, wherein a portion of the gate coupling structure extends over a portion of the first source/drain.

13. The chip of claim 12, further comprising an insulating layer between the portion of the gate coupling structure and the portion of the first source/drain.

14. The chip of claim 11, wherein the first source/drain comprises a first epitaxial (epi) layer and the second source/drain comprises a second epi layer.

15. The chip of claim 11, further comprising a frontside contact disposed on a top surface of the second source/drain, wherein the frontside contact is adjacent to a second side of the gate opposite the first side of the gate.

16. The chip of claim 15, further comprising a first signal route extending over the gate, wherein the gate coupling structure is coupled between the gate and the first signal route.

17. The chip of claim 16, further comprising:
a second signal route extending over the frontside contact; and
a via coupled between the frontside contact and the second signal route.

18. The chip of claim 15, further comprising:
a backside rail; and
a backside contact coupled between a bottom surface of the first source/drain and the backside rail.

19. The chip of claim 11, further comprising:
a first spacer adjacent to the first side of the gate, wherein the first spacer has a notch, and the gate coupling structure contacts the first side of the gate through the notch; and
a second spacer adjacent to a second side of the gate opposite the first side of the gate.

20. A chip, comprising:
a first source/drain;
a second source/drain;
a gate between the first source/drain and the second source/drain;
one or more channels coupled between the first source/drain and the second source/drain, wherein the one or more channels pass through the gate;
a gate coupling structure disposed on the gate, wherein a portion of the gate coupling structure extends over a portion of the first source/drain; and
an insulating layer between the portion of the gate coupling structure and the portion of the first source/drain.
